(19) United States
(12) Patent Application Publication
(10) Pub. No.: US 2022/0139636 A1
(43) Pub. Date: May 5, 2022

(54) SOLAR CELL

(71) Applicant: Panasonic Intellectual Property Management Co., Ltd., Osaka (JP)

(72) Inventor: YUMI MIYAMOTO, Osaka (JP)

(21) Appl. No.: 17/578,474

(22) Filed: Jan. 19, 2022

Related U.S. Application Data
(63) Continuation of application No. PCT/JP2019/045911, filed on Nov. 25, 2019.

(30) Foreign Application Priority Data
Aug. 27, 2019 (JP) 2019-155039

(51) Int. Cl. H01G 9/20

(52) U.S. Cl. CPC H01G 9/2027

(57) ABSTRACT

A solar cell having high conversion efficiency is provided. A solar cell of the present disclosure includes a first electrode, a second electrode, a photoelectric conversion layer disposed between the first electrode and the second electrode, and a first electron transport layer disposed between the first electrode and the photoelectric conversion layer. At least one electrode selected from the group consisting of the first electrode and the second electrode has translucency. The photoelectric conversion layer includes a perovskite compound containing a monovalent cation, a Sn cation and a halogen anion. The first electron transport layer includes porous niobium oxide.

### BACKGROUND

### 1. Technical Field

The present disclosure relates to a solar cell.

### 2. Description of the Related Art

In recent years, perovskite solar cells are being researched and developed. In perovskite solar cells, a perovskite compound represented by the chemical formula ABX₃ (wherein A is a monovalent cation, B is a divalent cation and X is a halogen anion) is used as a photoelectric conversion material.

Deli Shen et al., “Facile Deposition of Nb₂O₅ Thin Film as an Electron-Transporting Layer for Highly Efficient Perovskite Solar Cells”, ACS Applied Nano Materials, 2018, 1, 4101-4109 (Non Patent Literature 1) discloses a perovskite solar cell in which a perovskite compound represented by the chemical formula (CH₃NH₃)ₓ(HC(NH₂)₂)₁₋ₓPbI_{3-y}Br_{y} (wherein x satisfies 0<x<1, and y satisfies 0<y<3) is used as a photoelectric conversion material. Specifically, the perovskite solar cell disclosed in Non Patent Literature 1 uses a perovskite compound containing a Pb cation as a divalent cation. Further, Non Patent Literature 1 discloses that Nb₂O₅ is used as an electron transporting material and an organic semiconductor called Spiro-OMeTAD is used as a hole transporting material.

In recent years, lead-free photoelectric conversion materials for perovskite solar cells are demanded from, for example, an environmental viewpoint. For example, Mulmudi Hemant Kumar et Al., “Lead-free halide perovskite solar cells with high photocurrents realized through vacancy modulation”, Advanced Materials, 2014, Volume 26, Issue 41, 7122-7127 (Non Patent Literature 2) proposes a lead-free perovskite solar cell. Non Patent Literature 2 discloses that a perovskite compound represented by CsSnI₃ is used as a photoelectric conversion material, TiO₂ is used as an electron transporting material, and Spiro-OMeTAD is used as a hole transporting material.

### SUMMARY

One non-limiting and exemplary embodiment provides a tin-based perovskite solar cell having high conversion efficiency.

In one general aspect, the techniques disclosed here feature a solar cell including a first electrode, a second electrode, a photoelectric conversion layer disposed between the first electrode and the second electrode, and a first electron transport layer disposed between the first electrode and the photoelectric conversion layer, wherein at least one electrode selected from the group consisting of the first electrode and the second electrode has translucency, the photoelectric conversion layer includes a perovskite compound containing a monovalent cation, a Sn cation and a halogen anion, and the first electron transport layer includes porous niobium oxide.

The tin-based perovskite solar cell according to the present disclosure attains high conversion efficiency.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a graph illustrating values of current density and voltage measured of a lead-based perovskite solar cell and a tin-based perovskite solar cell fabricated by the present inventor;

FIG. 2 is a graph illustrating relationships between the voltage and the current density of solar cells studied with various energy offsets between a photoelectric conversion layer and an electron transport layer of the solar cells;

FIG. 3 illustrates a sectional view of a solar cell according to an embodiment;

FIG. 4 illustrates a sectional view of a modified example of the solar cell according to the embodiment;

FIG. 5A illustrates an electron diffraction image of a first electron transport layer of EXAMPLE 1;

FIG. 5B illustrates an electron diffraction image of a first electron transport layer of EXAMPLE 2;

FIG. 5C illustrates an electron diffraction image of a first electron transport layer of EXAMPLE 5;

FIG. 6A illustrates a scanning electron microscope (SEM) image of porous niobium oxide in the first electron transport layer of EXAMPLE 2; and

FIG. 6B illustrates a SEM image of the porous niobium oxide of EXAMPLE 2 after binarization.

### DETAILED DESCRIPTIONS

### Definition of Terms

As used herein, the term “perovskite compound” means a perovskite crystal structure represented by the chemical formula ABX₃ (wherein A is a monovalent cation, B is a divalent cation and X is a halogen anion) or a structure having a similar crystal.

As used herein, the term “tin-based perovskite compound” means a perovskite compound containing tin.

As used herein, the term “tin-based perovskite solar cell” means a solar cell that includes a tin-based perovskite compound as a photoelectric conversion material.

As used herein, the term “lead-based perovskite compound” means a perovskite compound containing lead.

As used herein, the term “lead-based perovskite solar cell” means a solar cell that includes a lead-based perovskite compound as a photoelectric conversion material.

### Underlying Knowledge Forming Basis of the Present Disclosure

The underlying knowledge forming the basis of the present disclosure will be described below.

Tin-based perovskite compounds have a bandgap of about 1.4 eV and are therefore suited as photoelectric conversion materials for solar cells. However, conventional tin-based perovskite solar cells, in spite of their high theoretical conversion efficiency, exhibit lower conversion efficiency than lead-based perovskite solar cells. FIG.

1 illustrates values of current density and voltage measured of a lead-based perovskite solar cell and a conventional tin-based perovskite solar cell fabricated by the present inventor. The lead-based perovskite solar cell and the tin-based perovskite solar cell used for the measurement of current density and voltage had a multilayer structure represented by substrate/first electrode/electron transport layer/porous layer/photoelectric conversion layer/hole transport layer/second electrode. The respective configurations of the cells are as follows.

(Lead-based Perovskite Solar Cell)
Substrate: Glass substrate
First electrode: Mixture of indium-tin composite oxide (ITO) and antimony-doped tin oxide (ATO)
Electron transport layer: Compact TiO₂ (c-TiO₂)
Porous layer: Mesoporous TiO₂ (mp-TiO₂)
Photoelectric conversion layer: HC(NH₂)₂PbI₃
Hole transport layer: 2,2′,7,7′-Tetrakis-(N,N-di-p-methoxyphenylamine) 9,9′-spirobifluorene (hereinafter, “spiro-OMeTAD”)
Second electrode: Gold

(Tin-based Perovskite Solar Cell)
Substrate: Glass substrate
First electrode: Mixture of indium-tin composite oxide (ITO) and antimony-doped tin oxide (ATO)
Electron transport layer: Compact TiO₂ (c-TiO₂)
Porous layer: Mesoporous TiO₂ (mp-TiO₂)
Photoelectric conversion layer: HC(NH₂)₂SnI₃
Hole transport layer: Poly[bis(4-phenyl)(2,4,6-trimethylphenyl)amine] (hereinafter, “PTAA”)
Second electrode: Gold

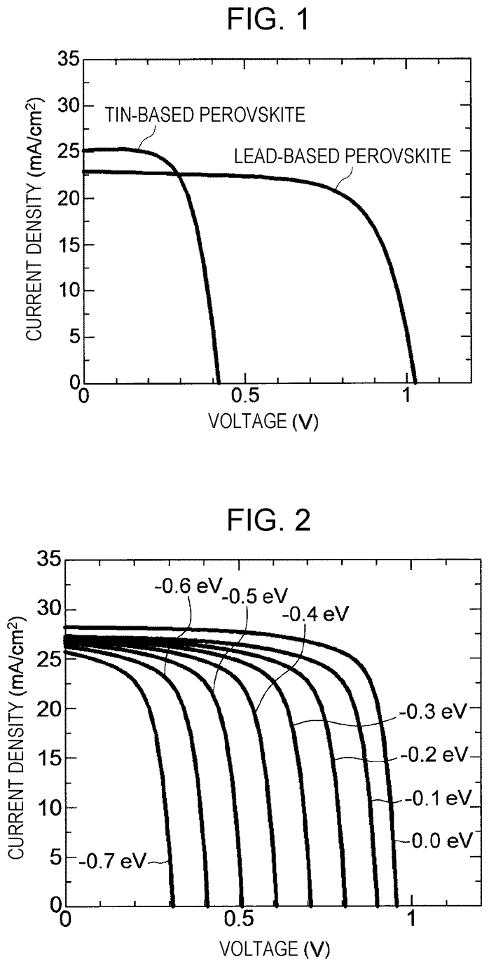

From FIG. 1, it can be seen that the open circuit voltage of a conventional tin-based perovskite solar cell is lower than that of a lead-based perovskite solar cell. This fact is probably a reason why the conversion efficiency of conventional tin-based perovskite solar cells is lower than the conversion efficiency of lead-based perovskite solar cells. The low open circuit voltage is probably ascribed to a large difference in energy level at the lower end of the conduction band between a tin-based perovskite compound and an electron transporting material forming an electron transport layer, and to the consequent recombination of carriers at the interface between the electron transport layer and the photoelectric conversion layer. In the following, the “difference in energy level at the lower end of the conduction band of an electron transporting material forming an electron transport layer, relative to that of a photoelectric conversion material forming a photoelectric conversion layer” is defined as the “energy offset”. Specifically, the energy offset is the difference obtained by subtracting the “energy level at the lower end of the conduction band of a photoelectric conversion material forming a photoelectric conversion layer” from the “energy level at the lower end of the conduction band of an electron transporting material forming an electron transport layer”. As used herein, the value of “energy level at the lower end of the conduction band” is a value relative to the vacuum level.

The energy level at the lower end of the conduction band of a tin-based perovskite compound is, for example, −3.5 eV. On the other hand, the energy level at the lower end of the conduction band of a lead-based perovskite compound is, for example, −4.0 eV. That is, the energy level at the lower end of the conduction band of a tin-based perovskite compound is energetically shallower than the energy level at the lower end of the conduction band of a lead-based perovskite compound. Here, a typical electron transporting material used in a lead-based perovskite solar cell is, for example, TiO₂. The energy level at the lower end of the conduction band of TiO₂ is −4.0 eV. When TiO₂ or other electron transporting material used in a lead-based perovskite solar cell is used in an electron transport layer in a tin-based perovskite solar cell, a difference in energy (an energy offset) is produced at the interface between the electron transporting material and the tin-based perovskite compound. For example, the difference in energy level at the lower end of the conduction band gives rise to an energy offset of −0.5 eV at the interface between TiO₂ and the tin-based perovskite compound. The presence of an energy offset increases the probability of electrons being present near the interface and thus increases the probability that the carriers will recombine at the interface, causing a loss of open circuit voltage. That is, a tin-based perovskite solar cell that combines a tin-based perovskite compound with an electron transporting material used in a lead-based perovskite solar cell has a lowered open circuit voltage as described above. As a result, the conversion efficiency of the solar cell is disadvantageously lowered.

FIG. 2 is a graph illustrating relationships between the voltage and the current density of solar cells studied with various energy offsets between a photoelectric conversion layer and an electron transport layer of the solar cells. The relationships are calculated by device simulation (software name: SCAPS). FIG. 2 illustrates simulation results for the cases where the energy offsets between the photoelectric conversion layer and the electron transport layer are 0.0 eV, −0.1 eV, −0.2 eV, −0.3 eV, −0.4 eV, −0.5 eV, −0.6 eV and −0.7 eV. As clear from FIG. 2, it is necessary to reduce the energy offset to 0.3 eV or less in absolute value in order to obtain high efficiency (for example, a voltage of 0.7 V and a current density of greater than or equal to 27 mA/cm²). Thus, a new electron transporting material that is optimum for combination with a tin-based perovskite compound is demanded.

The present inventor has found that niobium oxide such as, for example, Nb₂O₅ may be used as an electron transporting material in a tin-based perovskite solar cell in order to reduce the energy offset between a photoelectric conversion layer and an electron transport layer. Niobium oxide has electron affinity similar to that of a tin-based perovskite compound. Thus, a tin-based perovskite solar cell using niobium oxide as an electron transporting material attains a reduced energy offset and high conversion efficiency.

The present inventor has also newly found that a tin-based perovskite solar cell using niobium oxide as an electron transporting material may achieve a further enhancement in conversion efficiency when the niobium oxide in the tin-based perovskite solar cell is porous.

Based on the above findings, the present inventor has invented a solar cell that includes a tin-based perovskite compound and has high conversion efficiency.

### Embodiment of the Present Disclosure

Hereinbelow, an embodiment of the present disclosure will be described in detail with reference to the drawings.

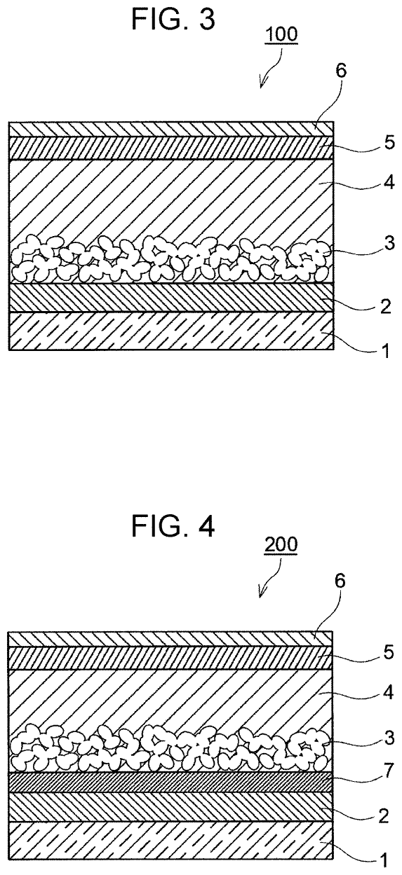

FIG. 3 illustrates a sectional view of a solar cell 100 according to the present embodiment. As illustrated in FIG. 3, the solar cell 100 of the present embodiment includes a substrate 1, a first electrode 2, a second electrode 6, a photoelectric conversion layer 4, a hole transport layer 5, and a first electron transport layer 3. The photoelectric conversion layer 4 is disposed between the first electrode 2 and the second electrode 6. The first electron transport layer 3 is located between the first electrode 2 and the photoelectric conversion layer 4. The first electrode 2 is opposed to the second electrode 6 so that the first electron transport layer 3 and the photoelectric conversion layer 4 are arranged between the first electrode 2 and the second electrode 6. At least one electrode selected from the group consisting of the first electrode 2 and the second electrode 6 has translucency. As used herein, the phrase “the electrode has translucency” means that the electrode transmits at least 10% of light having wavelengths of 200 nm to 2000 nm, at any of these wavelengths.

The photoelectric conversion layer 4 includes, as a photoelectric conversion material, a perovskite compound including a monovalent cation, a Sn cation and a halogen anion. Hereinbelow, this perovskite compound may be written as the “perovskite compound according to the present embodiment”. The photoelectric conversion material is a light absorbing material.

The perovskite compound according to the present embodiment is, for example, a compound represented by the chemical formula ABX₃. In the chemical formula, A denotes a monovalent cation, B a divalent cation including a Sn cation, and X a halogen anion. In line with the commonly used expressions in perovskite compounds, A, B and X in the present specification are also written as A-site, B-site and X-site, respectively.

For example, the perovskite compound according to the present embodiment has a perovskite-type crystal structure represented by ABX₃. As an example of the above chemical formula, A is a monovalent cation, B is a Sn cation, and X is a halogen anion. That is, for example, a monovalent cation is located at the A-site, Sn²⁺ at the B-site, and a halogen anion at the X-site in the perovskite compound according to the present embodiment.

The monovalent cation located at the A-site is not particularly limited. Examples of the monovalent cations include organic cations and alkali metal cations. Examples of the organic cations include methylammonium cation (i.e., CH₃NH₃⁺), formamidinium cation (i.e., NH₂CHNH₂⁺), phenethylammonium cation (i.e., C₆H₅CH₂CH₂NH₃⁺) and guanidinium cation (i.e., CH₆N₃⁺). Examples of the alkali metal cations include cesium cation (Cs⁺).

For example, the monovalent cation includes at least one selected from the group consisting of formamidinium cation and methylammonium cation. When the perovskite compound according to the present embodiment includes at least one monovalent cation selected from the group consisting of formamidinium cation and methylammonium cation, the solar cell 100 may attain higher conversion efficiency. The monovalent cation may be a combination of cations principally including at least one selected from the group consisting of formamidinium cation and methylammonium cation. The phrase that the monovalent cation is a combination of cations principally including at least one selected from the group consisting of formamidinium cation and methylammonium cation means that the total molar amount of the formamidinium cation and the methylammonium cation represents the largest proportion of the total molar amount of the monovalent cations. The monovalent cation may be at least one selected from the group consisting of formamidinium cation and methylammonium cation.

For example, the halogen anion located at the X-site includes iodide ion. When the perovskite compound according to the present embodiment includes iodide ion as the halogen anion, the solar cell 100 may attain higher conversion efficiency. The halogen anion may be a combination of anions principally including iodide ion. The phrase that the halogen anion is a combination of anions principally including iodide ion means that the molar amount of iodide ion represents the largest proportion of the total molar amount of the halogen anions. The halogen anion may be iodide ion.

The A-site, the B-site and the X-site may be each occupied by a plurality of kinds of ions.

The photoelectric conversion layer 4 may include a material other than the photoelectric conversion material. For example, the photoelectric conversion layer 4 may further include a quencher substance for reducing the defect density of the perovskite compound according to the present embodiment. Examples of the quencher substances include fluorine compounds such as tin fluoride.

The first electron transport layer 3 includes porous niobium oxide as an electron transporting material. Niobium oxide is advantageous in that the difference in energy level at the lower end of the conduction band is small between niobium oxide and the perovskite compound according to the present embodiment. Specifically, the difference between the energy level at the lower end of the conduction band of the porous niobium oxide contained in the first electron transport layer 3 and the energy level at the lower end of the conduction band of the perovskite compound according to the present embodiment is, for example, less than 0.3 eV in absolute value. By virtue of the first electron transport layer 3 including porous niobium oxide, the solar cell 100 may attain higher conversion efficiency.

The porous niobium oxide contained in the first electron transport layer 3 may be amorphous. When the first electron transport layer 3 includes amorphous niobium oxide, the solar cell 100 may attain higher conversion efficiency.

The porous niobium oxide contained in the first electron transport layer 3 may be represented by the chemical formula Nb₂₍₁₊ₓ₎O₅₍ᵢ₋ₓ₎. In the chemical formula, x may be greater than or equal to −0.15 and less than or equal to +0.15. The value of x may be determined by X-ray photoelectron spectroscopy (hereinafter, “XPS”) or may be alternatively obtained by energy dispersive X-ray spectroscopy (hereinafter, “EDX”), ICP emission spectroscopy or Rutherford backscattering spectrometry (hereinafter, “RBS”).

In the porous niobium oxide contained in the first electron transport layer 3, the molar ratio (Nb/O) of niobium to oxygen may be greater than or equal to 0.31 and less than or equal to 0.41. In other words, the porous niobium oxide may have a Nb/O molar ratio of greater than or equal to 0.31 and less than or equal to 0.41. When the niobium oxide satisfies such a molar ratio, the solar cell 100 may attain higher conversion efficiency. The molar ratio may be determined by XPS or may be alternatively obtained by EDX, ICP emission spectroscopy or RBS.

The porous niobium oxide contained in the first electron transport layer 3 may be Nb₂O₅. When the first electron transport layer 3 includes Nb₂O₅, the solar cell 100 may attain higher conversion efficiency.

The first electron transport layer 3 may be composed of a porous body. That is, the first electron transport layer 3 may be a porous layer. When the first electron transport layer 3 is a porous layer and when the first electron transport layer 3 is in contact with the first electrode 2 and the photoelectric conversion layer 4, the voids in the porous layer are continuous, for example, from the portion in contact with the first electrode 2 to the portion in contact with the photoelectric conversion layer 4. In this case, the material of the photoelectric conversion layer 4 may fill the voids in the porous layer and may reach the surface of the first electrode 2. Thus, the photoelectric conversion layer 4 may transfer electrons not only with the first electron transport layer 3 but also with the first electrode 2, and the electrons may move from the photoelectric conversion layer 4 to the first electrode 2 efficiently through the first electron transport layer 3 or directly.

The first electron transport layer 3 may further include a compound other than niobium oxide, may principally include niobium oxide, may essentially consist of niobium oxide, or may consist solely of niobium oxide. Here, the phrase “the first electron transport layer 3 principally includes niobium oxide” means that the first electron transport layer 3 includes greater than or equal to 50 mol % of niobium oxide, and may include, for example, greater than or equal to 60 mol % of niobium oxide. The phrase “the first electron transport layer 3 essentially consists of niobium oxide” means that the first electron transport layer 3 includes greater than or equal to 90 mol % of niobium oxide, and may include, for example, greater than or equal to 95 mol % of niobium oxide.

As used herein, the term “porous” means that a substance has pores inside. That is, porous niobium oxide is niobium oxide having pores inside. In, for example, porous niobium oxide, the pores are regions in which niobium oxide is not present. The sizes of the individual pores may be the same as or different from one another.

The first electron transport layer 3 may or may not be in contact with the photoelectric conversion layer 4. When the first electron transport layer 3 is in contact with the photoelectric conversion layer 4, the porous niobium oxide may be present on the surface, of the first electron transport layer 3, in contact with the photoelectric conversion layer 4. The first electron transport layer 3 may include an additional electron transporting material other than the porous niobium oxide. The solar cell 100 may include a plurality of electron transport layers formed of different electron transporting materials from one another. In that case, for example, the first electron transport layer 3 is arranged at a position where the first electron transport layer 3 is in contact with the photoelectric conversion layer 4.

For example, the thickness of the first electron transport layer 3 may be greater than or equal to 1 nm and less than or equal to 500 nm. When the first electron transport layer 3 has a thickness in this range, the first electron transport layer 3 may exhibit sufficient electron transport properties while maintaining low resistance. Thus, the solar cell 100 may attain high conversion efficiency.

The porosity in the porous niobium oxide contained in the first electron transport layer 3 may be, for example, greater than or equal to 2% and less than or equal to 40%. When the porosity in the porous niobium oxide is greater than or equal to 2% and less than or equal to 40%, the solar cell 100 according to the present embodiment may effectively attain enhancements in short-circuit current and conversion efficiency. The porosity in the porous niobium oxide may be greater than or equal to 5% and less than or equal to 35%. In other words, the porous niobium oxide may have a porosity of greater than or equal to 5% and less than or equal to 35%. When the porous niobium oxide has a porosity of greater than or equal to 5% and less than or equal to 35%, the solar cell 100 may attain a high short-circuit current and high conversion efficiency. Here, the porosity in the porous niobium oxide contained in the first electron transport layer 3 may be determined with respect to an image (a SEM image) of the porous niobium oxide taken by SEM. Specifically, a SEM image of the surface of the porous niobium oxide is analyzed first to obtain the area of solid regions and the area of void regions. Next, the proportion is calculated of the area of void regions in the total of the area of solid regions and the area of void regions (that is, the total area). The calculated proportion of the area of void regions is the porosity in the porous niobium oxide. The solid regions and the void regions in the SEM image may be identified as follows. First, the SEM image is binarized with an image processing software (for example, “ImageJ” (manufactured by the National Institutes of Health (NIH))). In the binarized SEM image, bright parts (that is, white parts) are recognized as solid regions, and dark parts (that is, black parts) are recognized as void regions. Incidentally, image processing such as conversion to gray scale format may be further performed in order to clarify the contrast of the SEM image.

The average of the pore diameters of the porous niobium oxide contained in the first electron transport layer 3 may be, for example, greater than or equal to 1 nm and less than or equal to 200 nm, or greater than or equal to 1 nm and less than or equal to 132 nm. In other words, the porous niobium oxide may have an average pore diameter of, for example, greater than or equal to 1 nm and less than or equal to 200 nm. The porous niobium oxide may have an average pore diameter of greater than or equal to 1 nm and less than or equal to 132 nm. Here, the average of the pore diameters of the porous niobium oxide may be determined with respect to a SEM image of the porous niobium oxide taken by SEM. Specifically, thirty pores are selected at random from among the pores seen in a SEM image of the surface of the porous niobium oxide. Here, the regions identified as pores in the SEM image are the regions recognized as void regions in the determination of the porosity in the porous niobium oxide. That is, dark parts in the SEM image are recognized as pores. Next, the diameters of the thirty pores selected are measured as the pore diameters. In the case where a single pore has a plurality of values of diameter (for example, when the shape of the pore is elliptical), the value of the smallest diameter is adopted as the value of diameter of that pore. The values of pore diameter measured of the thirty pores are averaged to give an average pore diameter. The pore diameters in the SEM image may be measured using an image processing software (for example, “ImageJ” (manufactured by NIH)), or may be measured with an instrument for measuring length such as a ruler.

In the solar cell 100 illustrated in FIG. 3, the first electrode 2, the first electron transport layer 3, the photoelectric conversion layer 4, the hole transport layer 5 and the second electrode 6 are stacked in this order on the substrate 1. The solar cell 100 does not necessarily have the substrate 1. The solar cell 100 does not necessarily have the hole transport layer 5.

Next, the basic working effects of the solar cell 100 will be described. When the solar cell 100 is irradiated with light, the photoelectric conversion layer 4 absorbs the light and generates excited electrons and holes. The excited electrons move to the first electron transport layer 3. On the other hand, the holes generated in the photoelectric conversion layer 4 move to the hole transport layer 5. The first electron transport layer 3 is electrically connected to the first electrode 2. The hole transport layer 5 is electrically connected to the second electrode 6. An electric current is taken out from the first electrode 2 functioning as a negative electrode and the second electrode 6 functioning as a positive electrode.

For example, the solar cell 100 is fabricated by the following method.

First, a first electrode 2 is formed on the surface of a substrate 1 by a chemical vapor deposition method (hereinafter, “CVD”) or a sputtering method.

Next, a first electron transport layer 3 is formed on the first electrode 2 by an application method such as a spin coating method. The first electron transport layer 3 includes porous niobium oxide. When the first electron transport layer 3 is formed by a spin coating method, for example, a solution of a Nb raw material is provided. The solution is heated at a predetermined temperature to give a dispersion of niobium oxide. A porosifier such as, for example, ethylcellulose or polystyrene-polyethylene oxide (hereinafter, “PS-PEO”) is added to the dispersion of niobium oxide obtained, and thereby a porous niobium oxide feedstock solution is prepared. The porous niobium oxide feedstock solution is spin-coated onto the first electrode 2 to form a coating film. The coating film is heat-treated at a predetermined temperature in, for example, air. Examples of the Nb raw materials include niobium alkoxides such as niobium ethoxide, niobium halides, niobium ammonium oxalate and niobium hydrogen oxalate. Examples of the solvents include ethanol, benzyl alcohol, water and 1,3-propanediol. The heat treatment temperature is, for example, greater than or equal to 100° C. and less than or equal to 700° C.

Next, a photoelectric conversion layer 4 is formed on the first electron transport layer 3. For example, the photoelectric conversion layer 4 may be fabricated by the following method. As an example, the photoelectric conversion layer 4 that is produced by the following method includes a perovskite compound represented by the chemical formula (HC(NH₂)₂)_{1-y}(C₆H₅CH₂CH₂NH₃)_{y}SnI₃ (hereinafter, sometimes abbreviated as “FA_{1-y}PEA_{y}SnI₃”). In FA_{1-y}PEA_{y}SnI₃, y satisfies 0<y<1.

First, SnI₂, HC(NH₂)₂I (hereinafter, “FAI”) and C₆H₅CH₂CH₂NH₃I (hereinafter, “PEAI”) are added to an organic solvent. For example, the organic solvent is a mixed solution of dimethyl sulfoxide (hereinafter, “DMSO”) and N,N-dimethylformamide (hereinafter, “DMF”) (for example, DMSO:DMF=1:1 (by volume)). The molar concentration of SnI₂ may be greater than or equal to 0.8 mol/L and less than or equal to 2.0 mol/L, or greater than or equal to 0.8 mol/L and less than or equal to 1.5 mol/L. The molar concentration of FAI may be greater than or equal to 0.8 mol/L and less than or equal to 2.0 mol/L, or greater than or equal to 0.8 mol/L and less than or equal to 1.5 mol/L. The molar concentration of PEAI may be greater than or equal to 0.1 mol/L and less than or equal to 0.5 mol/L, or greater than or equal to 0.1 mol/L and less than or equal to 0.3 mol/L.

Next, the solution obtained by adding SnI₂, FAI and PEAI to the organic solvent is heated to a temperature in the range of greater than or equal to 40° C. and less than or equal to 180° C. A mixture solution of SnI₂, FAI and PEAI is thus obtained. Subsequently, the mixture solution obtained is allowed to stand at room temperature.

Next, the mixture solution is applied onto the first electron transport layer 3 by a spin coating method, and is heated at a temperature in the range of greater than or equal to 40° C. and less than or equal to 200° C. for an amount of time in the range of greater than or equal to 15 minutes and less than or equal to 1 hour. A photoelectric conversion layer 4 is thus obtained. When the mixture solution is applied by a spin coating method, a poor solvent may be dropped during the spin coating process. Examples of the poor solvents include toluene, chlorobenzene and diethyl ether.

The mixture solution for forming a photoelectric conversion layer 4 may contain a quencher substance such as tin fluoride. The concentration of the quencher substance may be greater than or equal to 0.05 mol/L and less than or equal to 0.4 mol/L. The quencher substance suppresses the generation of defects, specifically, the generation of Sn vacancies in the photoelectric conversion layer 4. The increase in Sn⁴⁺ promotes the formation of Sn vacancies.

Next, a hole transport layer 5 is formed on the photoelectric conversion layer 4. For example, the hole transport layer 5 is formed by an application method or a printing method. Examples of the application methods include doctor blade methods, bar coating methods, spraying methods, dip coating methods and spin coating methods. Examples of the printing methods include screen printing methods. A plurality of materials may be mixed to form a hole transport layer 5, and the hole transport layer 5 may be then pressed or heat-treated. When the material for the hole transport layer 5 is an organic low-molecular substance or an inorganic semiconductor, the hole transport layer 5 may be formed by, for example, a vacuum deposition method.

Next, a second electrode 6 is formed on the hole transport layer 5. A solar cell 100 is thus obtained. The second electrode 6 may be formed by a CVD method or a sputtering method.

Hereinbelow, the components constituting the solar cell 100 will be described in greater detail.

(Substrate 1)

The substrate 1 supports the first electrode 2, the first electron transport layer 3, the photoelectric conversion layer 4 and the second electrode 6. The substrate 1 may be formed from a transparent material. For example, the substrate 1 is a glass substrate or a plastic substrate. The plastic substrate may be, for example, a plastic film. When the first electrode 2 has sufficient strength, the solar cell 100 does not necessarily have the substrate 1 because the first electrode 2 can support the electron transport layer 3, the photoelectric conversion layer 4 and the second electrode 6.

(First Electrode 2 and Second Electrode 6)

The first electrode 2 and the second electrode 6 have conductivity. At least one of the first electrode 2 and the second electrode 6 has translucency. For example, the translucent electrode may transmit light from the visible region to the near infrared region. The translucent electrode may be formed from at least one of transparent and conductive metal oxides and metal nitrides.

Examples of the metal oxides include:

(i) titanium oxides doped with at least one selected from the group consisting of lithium, magnesium, niobium and fluorine,

(ii) gallium oxides doped with at least one selected from the group consisting of tin and silicon,

(iii) indium-tin composite oxides,

(iv) tin oxides doped with at least one selected from the group consisting of antimony and fluorine, and

(v) zinc oxides doped with at least one selected from the group consisting of boron, aluminum, gallium and indium. Two or more kinds of metal oxides may be used in combination as a composite.

Examples of the metal nitrides include gallium nitrides doped with at least one selected from the group consisting of silicon and oxygen. Two or more kinds of metal nitrides may be used in combination.

The metal oxides and the metal nitrides may be used in combination.

The translucent electrode may be formed using a non-transparent material. In this case, the translucent electrode may be formed by, for example, creating a pattern through which light is transmitted. Examples of the light-transmitting patterns include linear (that is, stripe) patterns, wavy patterns, grid (that is, mesh) patterns, and punching metal-like patterns in which a large number of micro through-holes are regularly or irregularly arranged. When the electrode has such a pattern, light can be transmitted through regions where there is no electrode material. Examples of the non-transparent electrode materials include platinum, gold, silver, copper, aluminum, rhodium, indium, titanium, iron, nickel, tin, zinc, and alloys containing any of these metals. Conductive carbon materials may also be used.

The solar cell 100 includes the first electron transport layer 3 between the photoelectric conversion layer 4 and the first electrode 2. Therefore, the first electrode 2 does not need to block holes moving from the photoelectric conversion layer 4. Thus, the first electrode 2 may be formed of a material capable of forming an ohmic contact with the photoelectric conversion layer 4.

When the solar cell 100 does not include the hole transport layer 5, the second electrode 6 is formed of a material that has electron-blocking properties to block electrons moving from the photoelectric conversion layer 4. In this case, the second electrode 6 does not make an ohmic contact with the photoelectric conversion layer 4. The electron-blocking properties by which electrons moving from the photoelectric conversion layer 4 are blocked mean that the electrode allows for the passage of only holes generated in the photoelectric conversion layer 4 and blocks the passage of electrons. The Fermi energy level of the material having electron-blocking properties is lower than the energy level at the lower end of the conduction band of the photoelectric conversion layer 4. The Fermi energy level of the material having electron-blocking properties may be lower than the Fermi energy level of the photoelectric conversion layer 4. Specifically, the second electrode 6 may be formed from platinum, gold or a carbon material such as graphene. These materials have electron-blocking properties but do not have translucency. Thus, when a translucent second electrode 6 is to be fabricated using such a material, a light-transmitting pattern such as one described hereinabove is formed in the second electrode 6. When the solar cell 100 includes the hole transport layer 5 between the photoelectric conversion layer 4 and the second electrode 6, the second electrode 6 does not necessarily have electron-blocking properties to block electrons moving from the photoelectric conversion layer 4. Thus, the second electrode 6 may be formed of a material capable of making an ohmic contact with the photoelectric conversion layer 4.

The light transmittance of the first electrode 2 and the second electrode 6 may be greater than or equal to 50%, or may be greater than or equal to 80%. The wavelength of light transmitted through the electrode depends on the wavelength absorbed by the photoelectric conversion layer 4. The thicknesses of the first electrode 2 and the second electrode 6 are, for example, each greater than or equal to 1 nm and less than or equal to 1000 nm.

(First Electron Transport Layer 3)

The first electron transport layer 3 includes porous niobium oxide as an electron transporting material. As described hereinabove, the first electron transport layer 3 may further include an electron transporting material other than the porous niobium oxide.

The electron transporting material other than the porous niobium oxide (hereinafter, sometimes written as the “additional electron transporting material”) that may be contained in the first electron transport layer 3 may be a material known as an electron transporting material for solar cells. The additional electron transporting material may be a semiconductor having a bandgap of greater than or equal to 3.0 eV. When the first electron transport layer 3 includes a semiconductor having a bandgap of greater than or equal to 3.0 eV, visible light and infrared light may reach the photoelectric conversion layer 4. Examples of such semiconductors include organic or inorganic n-type semiconductors.

Examples of the organic n-type semiconductors include imide compounds, quinone compounds, fullerenes and fullerene derivatives. Examples of the inorganic n-type semiconductors include metal oxides, metal nitrides and perovskite oxides. Examples of the metal oxides include oxides of Cd, Zn, In, Pb, Mo, W, Sb, Bi, Cu, Hg, Ti, Ag, Mn, Fe, V, Sn, Zr, Sr, Ga, Si or Cr. For example, TiO₂ may be used. Examples of the metal nitrides include GaN. Examples of the perovskite oxides include SrTiO₃ and CaTiO₃.

The first electron transport layer 3 offers an advantage that the photoelectric conversion layer 4 may be formed easily. The material for the photoelectric conversion layer 4 penetrates into the voids in the first electron transport layer 3 and consequently the first electron transport layer 3 serves as a scaffold for the photoelectric conversion layer 4. That is, the first electron transport layer 3 reduces the probability that the material for the photoelectric conversion layer 4 will be repelled by or aggregated on the surface of the first electron transport layer 3. Thus, the first electron transport layer 3 as a scaffold allows the photoelectric conversion layer 4 to be formed as a uniform film. After a stack of the substrate 1, the first electrode 2 and the first electron transport layer 3 has been prepared, the photoelectric conversion layer 4 in the solar cell 100 may be formed by, for example, applying a mixture solution for the photoelectric conversion layer onto the first electron transport layer 3 by a spin coating method, and heating the wet film.

The first electron transport layer 3 will cause light to be scattered and will effectively increase the optical path length in which the light passes through the photoelectric conversion layer 4. It is expected that the increase in optical path length will lead to an increase in the amount of electrons and holes generated in the photoelectric conversion layer 4.

(Photoelectric Conversion Layer 4)

The photoelectric conversion layer 4 includes the perovskite compound according to the present embodiment. The photoelectric conversion layer 4 may principally include the perovskite compound according to the present embodiment. Here, the phrase “the photoelectric conversion layer 4 principally includes the perovskite compound according to the present embodiment” means that the photoelectric conversion layer 4 includes greater than or equal to 70 mass % of the perovskite compound according to the present embodiment. The photoelectric conversion layer 4 may include greater than or equal to 80 mass % of the perovskite compound according to the present embodiment. The photoelectric conversion layer 4 may contain impurities as long as the photoelectric conversion layer 4 includes the perovskite compound according to the present embodiment. The photoelectric conversion layer 4 may further include a compound dissimilar to the perovskite compound according to the present embodiment.

The thickness of the photoelectric conversion layer 4 is variable depending on the magnitude of its light absorption, but is, for example, greater than or equal to 100 nm and less than or equal to 10 μm. The thickness of the photoelectric conversion layer 4 may be greater than or equal to 100 nm and less than or equal to 1000 nm. The photoelectric conversion layer 4 may be formed by an application method using a solution.

(Hole Transport Layer 5)

The hole transport layer 5 is composed of an organic semiconductor or an inorganic semiconductor. Typical examples of the organic semiconductors used for the hole transport layer 5 include spiro-OMeTAD, PTAA, poly(3-hexylthiophene-2,5-diyl) (hereinafter, “P3HT”), poly(3,4-ethylenedioxythiophene) (hereinafter, “PEDOT”) and copper (II) phthalocyanine triple-sublimed grade (hereinafter, “CuPC”).

Examples of the inorganic semiconductors include Cu₂O, CuGaO₂, CuSCN, CuI, NiOₓ, MoOₓ, V₂O₅, and carbon materials such as graphene oxide.

The hole transport layer 5 may include a plurality of layers made of different materials from one another.

The thickness of the hole transport layer 5 may be greater than or equal to 1 nm and less than or equal to 1000 nm, greater than or equal to 10 nm and less than or equal to 500 nm, or greater than or equal to 10 nm and less than or equal to 50 nm. This range of thickness ensures that sufficient hole transporting properties will be exhibited while maintaining low resistance, and thus the photoelectric conversion efficiency will be increased.

The hole transport layer 5 may include a supporting electrolyte and a solvent. A supporting electrolyte and a solvent effectively stabilize the holes in the hole transport layer 5.

Examples of the supporting electrolytes include ammonium salts and alkali metal salts. Examples of the ammonium salts include tetrabutylammonium perchlorate, tetraethylammonium hexafluorophosphate, imidazolium salts and pyridinium salts. Examples of the alkali metal salts include lithium bis(trifluoromethanesulfonyl)imide (hereinafter, “LiTFSI”), LiPF₆, LiBF₄, lithium perchlorate and potassium tetrafluoroborate.

The solvent contained in the hole transport layer 5 may have high ion conductivity. The solvent may be an aqueous solvent or an organic solvent. To stabilize the solutes, the solvent may be an organic solvent. Examples of the organic solvents include heterocyclic compounds such as tert-butylpyridine, pyridine and n-methylpyrrolidone.

The solvent contained in the hole transport layer 5 may be an ionic liquid. An ionic liquid may be used alone or as a mixture with other solvents. Ionic liquids are preferable because of low volatility and high flame retardancy.

Examples of the ionic liquids include imidazolium compounds such as 1-ethyl-3-methylimidazolium tetracyanoborate, pyridine compounds, alicyclic amine compounds, aliphatic amine compounds and azonium amine compounds.

FIG. 4 illustrates a sectional view of a modified example of the solar cell according to the present embodiment. Unlike the solar cell 100 illustrated in FIG. 3, a solar cell 200 of the modified example includes a second electron transport layer 7. The second electron transport layer 7 is disposed between a first electrode 2 and a first electron transport layer 3, and includes compact niobium oxide.

In the solar cell 200 illustrated in FIG. 4, a first electrode 2, a second electron transport layer 7, a first electron transport layer 3, a photoelectric conversion layer 4, a hole transport layer 5 and a second electrode 6 are stacked in this order on a substrate 1. The solar cell 200 does not necessarily have the substrate 1. The solar cell 200 does not necessarily have the hole transport layer 5.

The second electron transport layer 7 includes compact niobium oxide. As used herein, the term “compact” means that a substance is a dense unit. Specifically, the term “compact” means that the porosity is less than or equal to 1%. Here, the porosity of a compact substance may be determined with respect to a SEM image of the surface of the substance taken by SEM. Specifically, the porosity of a compact substance may be obtained in the same manner as the porosity of the porous niobium oxide described hereinabove. First, a SEM image of the surface of the niobium oxide contained in the second electron transport layer 7 is analyzed to obtain the area of solid regions and the area of void regions. Next, the proportion is calculated of the area of void regions in the total of the area of solid regions and the area of void regions (that is, the total area). The calculated proportion of the area of void regions is the porosity. The solid regions and the void regions in the SEM image may be identified in the same manner as in the measurement of the porosity in the porous niobium oxide described hereinabove.

The compact niobium oxide contained in the second electron transport layer 7 may be amorphous.

The compact niobium oxide contained in the second electron transport layer 7 may be represented by the chemical formula Nb₂₍₁₊ₓ₎O₅₍₁₋ₓ₎. In the chemical formula, x may be greater than or equal to −0.15 and less than or equal to +0.15. The value of x may be determined by XPS or may be alternatively obtained by EDX, ICP emission spectroscopy or RBS.

In the compact niobium oxide contained in the second electron transport layer 7, the molar ratio (Nb/O) of niobium to oxygen may be greater than or equal to 0.31 and less than or equal to 0.41. When the niobium oxide satisfies such a molar ratio, the solar cell 200 may attain higher conversion efficiency. The molar ratio may be determined by XPS or may be alternatively obtained by EDX, ICP emission spectroscopy or RBS.

The compact niobium oxide contained in the second electron transport layer 7 may be Nb₂O₅. When the second electron transport layer 7 includes Nb₂O₅, the solar cell 200 may attain higher conversion efficiency.

The thickness of the second electron transport layer 7 may be greater than or equal to 8 nm and less than or equal to 350 nm. When the second electron transport layer 7 has a thickness in this range, the second electron transport layer 7 may exhibit sufficient electron transporting properties while maintaining low resistance.

The second electron transport layer 7 may be composed of a compact body. That is, the second electron transport layer 7 may be a compact layer. When the second electron transport layer 7 is in contact with the first electrode 2 and the first electron transport layer 3, and when the first electron transport layer 3 is a porous layer in contact with the photoelectric conversion layer 4, the voids in the porous layer are continuous, for example, from the portion in contact with the second electron transport layer 7 to the portion in contact with the photoelectric conversion layer 4. In this case, the material of the photoelectric conversion layer 4 may fill the voids in the porous layer and may reach the surface of the second electron transport layer 7. Thus, the photoelectric conversion layer 4 may transfer electrons directly not only with the first electron transport layer 3 but also with the second electron transport layer 7, and the electrons may move from the photoelectric conversion layer 4 to the first electrode 2 efficiently through the first electron transport layer 3 and the second electron transport layer 7 or through only the second electron transport layer 7.

Next, the basic working effects of the solar cell 200 will be described. When the solar cell 200 is irradiated with light, the photoelectric conversion layer 4 absorbs the light and generates excited electrons and holes. The excited electrons move to the first electron transport layer 3. On the other hand, the holes generated in the photoelectric conversion layer 4 move to the hole transport layer 5. As described hereinabove, the first electron transport layer 3 and the hole transport layer 5 are electrically connected to the first electrode 2 and the second electrode 6, respectively, and thus an electric current is taken out from the first electrode 2 functioning as a negative electrode and the second electrode 6 functioning as a positive electrode.

The solar cell 200 may be fabricated by the same method as the solar cell 100. For example, the second electron transport layer 7 is formed on the first electrode 2 by an application method such as a spin coating method, or a sputtering method. Here, an example will be described in which the second electron transport layer 7 is a compact layer composed of compact niobium oxide. When, for example, the second electron transport layer 7 is formed by a spin coating method, a solution of a predetermined concentration of a Nb raw material in a solvent is provided. Next, the solution is spin-coated onto the first electrode 2 to form a coating film. The coating film is heat-treated at a predetermined temperature in, for example, air. Examples of the Nb raw materials include niobium alkoxides such as niobium ethoxide, niobium halides, niobium ammonium oxalate and niobium hydrogen oxalate. Examples of the solvents include isopropanol and ethanol. The heat treatment temperature is, for example, greater than or equal to 30° C. and less than or equal to 1500° C.

### EXAMPLES

The present disclosure will be described in greater detail with reference to the following EXAMPLES.

### Example 1

In EXAMPLE 1, a solar cell 200 illustrated in FIG. 4 was fabricated as follows.

A glass substrate that had, on the surface thereof, a second electron transport layer 7 formed of compact niobium oxide was obtained from GEOMATEC Co., Ltd. The glass substrate had an indium-doped SnO₂ layer on the surface. The glass substrate and the SnO₂ layer served as a substrate 1 and a first electrode 2, respectively. The glass substrate was a product manufactured by Nippon Sheet Glass Co., Ltd. and had a thickness of 1 mm. The second electron transport layer 7 of compact niobium oxide was formed by a sputtering method at 200° C. The thickness of the second electron transport layer 7 was 15 nm.

A SEM image of the surface of the second electron transport layer 7 was taken. No voids were found in the SEM image. That is, it was confirmed from the SEM image that the second electron transport layer 7 disposed on the glass substrate was clearly a compact body.

Next, a porous niobium oxide feedstock solution for fabricating a first electron transport layer 3 was prepared. Specifically, a benzyl alcohol solution was prepared which contained niobium ethoxide (Nb(OCH₂CH₃)₅ (manufactured by Sigma-Aldrich)). The concentration of niobium ethoxide in this solution was 0.074 mol/L. The solution was sealed in a pressure vessel and was heated at 180° C. for 12 hours. Thereafter, the solution was allowed to cool to room temperature. A niobium oxide dispersion was thus obtained. An ethylcellulose solution was prepared by dissolving ethylcellulose into ethanol so that the concentration would be 5.6 mass % and further adding 45 μL of terpineol. The niobium oxide dispersion and the ethylcellulose solution prepared as described above were mixed together so that niobium oxide:ethylcellulose=1:2.4 (by mass). A porous niobium oxide feedstock solution was thus prepared.

The porous niobium oxide feedstock solution was spin-coated onto the second electron transport layer 7 to form a coating film. The coating film was preheated at 100° C. for 10 minutes. The preheated film was then placed into an electric furnace and was heat-treated at 500° C. for 30 minutes to give a first electron transport layer 3 formed of porous niobium oxide.

Next, SnI₂ (manufactured by Sigma-Aldrich), SnF₂ (manufactured by Sigma-Aldrich), FAI (manufactured by GreatCell Solar Materials) and PEAI (manufactured by GreatCell Solar Materials) were added to a DMSO-DMF mixed solvent to give a mixture solution. The DMSO:DMF volume ratio in the mixture solution was 1:1. The concentration of SnI₂ in the mixture solution was 1.5 mol/L. The concentration of SnF₂ in the mixture solution was 0.15 mol/L. The concentration of FAI in the mixture solution was 1.5 mol/L. The concentration of PEAI in the mixture solution was 0.3 mol/L.

In a glove box, 80 μL of the mixture solution was applied onto the first electron transport layer 3 by a spin coating method to form a coating film. The film thickness of the coating film was 450 nm. A portion of the mixture solution used in the formation of the coating film penetrated into the voids in the first electron transport layer 3. Thus, the above film thickness of the coating film includes the thickness of the first electron transport layer 3. Next, the coating film was heat-treated on a hot plate at 120° C. for 30 minutes to form a photoelectric conversion layer 4. The photoelectric conversion layer 4 principally included a perovskite compound of the chemical formula FA_{0.83}PEA_{0.17}SnI₃. The energy level at the lower end of the conduction band of the perovskite compound of the chemical formula FA_{0.83}PEA_{0.17}SnI₃ was −3.4 eV relative to the vacuum level. The method for measuring the energy level at the lower end of the conduction band will be described later.

Next, in the glove box, 80 μL of a toluene solution containing 10 mg/mL of PTAA (manufactured by Sigma-Aldrich) was applied onto the photoelectric conversion layer 4 by a spin coating method to form a hole transport layer 5. The observation by sectional SEM analysis (Helios G3: manufactured by FEI) showed that the thickness of the hole transport layer 5 was 10 nm.

Lastly, gold was deposited onto the hole transport layer 5 to a thickness of 120 nm to form a second electrode 6. A solar cell of EXAMPLE 1 was thus obtained.

### Example 2

In EXAMPLE 2, a solar cell 200 was obtained in the same manner as in EXAMPLE 1 except for the following items (i) and (ii).

(i) In the fabrication of the first electron transport layer 3, the ethylcellulose solution was replaced by a PS-PEO solution prepared by dissolving PS-PEO (manufactured by Polymer Source, Inc., molecular weight of polystyrene moiety: 42 kg/mol, molecular weight of polyethylene oxide moiety: 11.5 kg/mol) into tetrahydrofuran so that the concentration would be 0.079 mmol/L.
(ii) In the fabrication of the first electron transport layer 3, a porous niobium oxide feedstock solution was prepared by admixing 6.6 mL of the above PS-PEO solution with a solution of 0.925 mmol of niobium chloride in 9.21 mL of ethanol and 0.38 mL of water.

### EXAMPLE 3

In EXAMPLE 3, a solar cell 200 was obtained in the same manner as in EXAMPLE 2 except for the following item (i).

(i) In the fabrication of the first electron transport layer 3, a PS-PEO solution was prepared using PS-PEO (manufactured by Polymer Source, Inc.) having a molecular weight of polystyrene moiety of 51 kg/mol and a molecular weight of polyethylene oxide moiety of 11.5 kg/mol, instead of the PS-PEO (molecular weight of polystyrene moiety: 42 kg/mol, molecular weight of polyethylene oxide moiety: 11.5 kg/mol).

### Example 4

In EXAMPLE 4, a solar cell 200 was obtained in the same manner as in EXAMPLE 2 except for the following item (i).

(i) In the fabrication of the first electron transport layer 3, a PS-PEO solution was prepared using PS-PEO (manufactured by Polymer Source, Inc.) having a molecular weight of polystyrene moiety of 144 kg/mol and a molecular weight of polyethylene oxide moiety of 11.5 kg/mol, instead of the PS-PEO (molecular weight of polystyrene moiety: 42 kg/mol, molecular weight of polyethylene oxide moiety: 11.5 kg/mol).

### Example 5

In EXAMPLE 5, a solar cell 200 was obtained in the same manner as in EXAMPLE 1 except for the following item (i).

(i) In the fabrication of the first electron transport layer 3, the porous niobium oxide feedstock solution was replaced by a porous niobium oxide dispersion prepared by adding 0.45 mL of a 5.6 mass % ethanol solution of ethylcellulose to 0.25 mL of a niobium oxide dispersion (manufactured by TAKI CHEMICAL CO., LTD.) containing 6 mass % of niobium oxide.

### Comparative Example 1

In COMPARATIVE EXAMPLE 1, a solar cell 200 was obtained in the same manner as in EXAMPLE 1 except that the first electron transport layer 3 was not formed. That is, the solar cell 200 of COMPARATIVE EXAMPLE 1 did not include the first electron transport layer including porous niobium oxide.

### Comparative Example 2

In COMPARATIVE EXAMPLE 2, a solar cell 200 was obtained in the same manner as in COMPARATIVE EXAMPLE 1 except for the following item (i).

(i) In the fabrication of the photoelectric conversion layer 4, the tin-based perovskite compound of the chemical formula FA_{0.83}PEA_{0.17}SnI₃ was replaced by a lead-based perovskite compound of the chemical formula FA_{0.83}PEA_{0.17}PbI₃.

The photoelectric conversion layer in the solar cell 200 of COMPARATIVE EXAMPLE 2 was fabricated in the following manner. PbI₂ (manufactured by Sigma-Aldrich), FAI (manufactured by GreatCell Solar Materials) and PEAI (manufactured by GreatCell Solar Materials) were added to a DMSO-DMF mixed solvent to give a mixture solution. The DMSO:DMF volume ratio in the mixture solution was 1:1. The concentration of PbI₂ in the mixture solution was 1.5 mol/L. The concentration of PbF₂ in the mixture solution was 0.15 mol/L. The concentration of FAI in the mixture solution was 1.5 mol/L. The concentration of PEAI in the mixture solution was 0.3 mol/L. The photoelectric conversion layer 4 was fabricated in the same manner as in COMPARATIVE EXAMPLE 1 except that this mixture solution was used.

The energy level at the lower end of the conduction band of the perovskite compound of the chemical formula FA_{0.83}PEA_{0.17}PbI₃ was −4.0 eV relative to the vacuum level. The method for measuring the energy level at the lower end of the conduction band will be described later.

### Comparative Example 3

In COMPARATIVE EXAMPLE 3, a solar cell 200 was obtained in the same manner as in EXAMPLE 1 except for the following item (i).

(i) In the fabrication of the photoelectric conversion layer 4, the tin-based perovskite compound of the chemical formula FA_{0.83}PEA_{0.17}SnI₃ was replaced by a lead-based perovskite compound of the chemical formula FA_{0.83}PEA_{0.17}PbI₃.

The photoelectric conversion layer in the solar cell 200 of COMPARATIVE EXAMPLE 3 was fabricated in the same manner as the photoelectric conversion layer in the solar cell 200 of COMPARATIVE EXAMPLE 2.

### Comparative Example 4

In COMPARATIVE EXAMPLE 4, a solar cell 200 was obtained in the same manner as in EXAMPLE 1 except for the following items (i) and (ii).

(i) In the fabrication of the second electron transport layer 7, the ethanol solution containing niobium ethoxide was replaced by an ethanol solution containing zinc chloride (ZnCl₃) (manufactured by Wako Pure Chemical Industries, Ltd.) and having a zinc chloride concentration of 0.3 mol/L.
(ii) In the fabrication of the first electron transport layer 3, the porous niobium oxide feedstock solution was replaced by a porous zinc oxide feedstock solution prepared by admixing 2.14 mL of a 5.6 mass % ethanol solution of ethylcellulose with 0.98 mL of 0.47 mol/L zinc nitrate hexahydrate (manufactured by Wako Pure Chemical Industries, Ltd.).

### Comparative Example 5

In COMPARATIVE EXAMPLE 5, a solar cell 200 was obtained in the same manner as in EXAMPLE 1 except for the following items (i) and (ii).

(i) In the fabrication of the second electron transport layer 7, the ethanol solution containing niobium ethoxide was replaced by an ethanol solution containing aluminum chloride (AlCl₃) (manufactured by Wako Pure Chemical Industries, Ltd.) and having an aluminum chloride concentration of 0.3 mol/L.
(ii) In the fabrication of the first electron transport layer 3, the porous niobium oxide feedstock solution was replaced by a porous aluminum oxide feedstock solution prepared by admixing 4.15 mL of a 5.6 mass % ethanol solution of ethylcellulose with 0.48 g of an ethanol-IPA solution containing 15 wt % of aluminum oxide (manufactured by CIK NanoTek Corporation).

### Comparative Example 6

In COMPARATIVE EXAMPLE 6, a solar cell 200 was obtained in the same manner as in EXAMPLE 1 except for the following items (i) and (ii).

(i) In the fabrication of the second electron transport layer 7, the ethanol solution containing niobium ethoxide was replaced by an ethanol solution containing zirconium acetate dihydrate (ZrOCOCH₃.2H₂O) (manufactured by Sigma-Aldrich) and having a concentration of zirconium acetate dihydrate of 0.3 mol/L.
(ii) In the fabrication of the first electron transport layer 3, the porous niobium oxide feedstock solution was replaced by a porous zirconium oxide feedstock solution prepared by dissolving 300 mg of zirconium oxide paste (manufactured by SOLARONIX) into 1 mL of ethanol.

### Determination of Crystallinity of Porous Material of First Electron Transport Layer 3

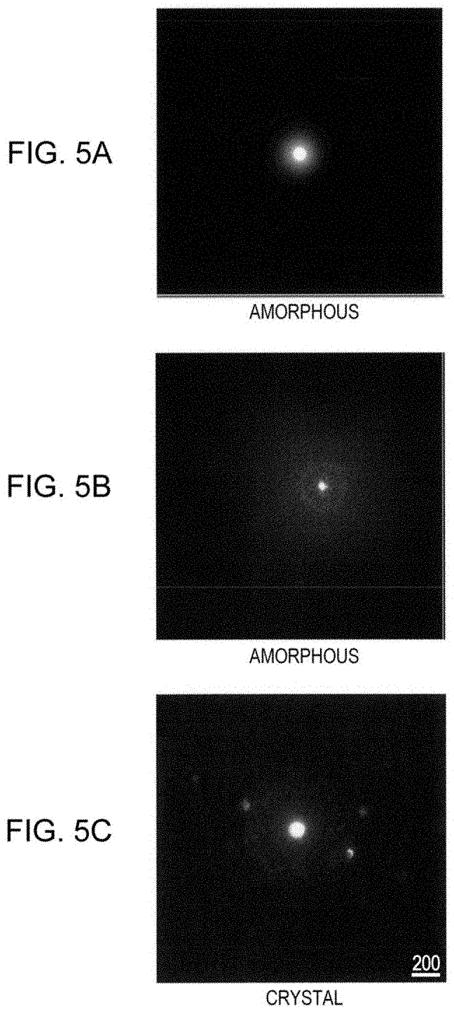

With respect to the solar cells 200 of EXAMPLES 1 to 5 and COMPARATIVE EXAMPLE 3, the crystallinity of the porous material of the first electron transport layer 3 was determined by an electron diffraction method. Electron diffraction was measured using an atomic resolution analytical electron microscope (ARM200F manufactured by JEOL Ltd.). The results are described in Table 1. FIG. 5A illustrates an electron diffraction image of the first electron transport layer 3 of EXAMPLE 1. FIG. 5B illustrates an electron diffraction image of the first electron transport layer 3 of EXAMPLE 2. FIG. 5C illustrates an electron diffraction image of the first electron transport layer 3 of EXAMPLE 5. As illustrated in FIGS. 5A and 5B, a halo pattern was seen in the electron diffraction images of the first electron transport layers 3 of EXAMPLES 1 and 2. This confirmed that the porous niobium oxides forming the first electron transport layers 3 of

EXAMPLES 1 and 2 were amorphous. Further, as illustrated in FIG. 5C, a plurality of white spots were seen in the electron diffraction image of the first electron transport layer 3 of EXAMPLE 5. This confirmed that the porous niobium oxide forming the first electron transport layer 3 of EXAMPLE 5 was a crystal.

### Method for Measuring Energy Level at Lower End of Conduction Band of Perovskite Compound

The energy level at the lower end of the conduction band of the perovskite compound in the photoelectric conversion layer 4 was calculated based on ultraviolet electron spectroscopy measurement and transmittance measurement. Specifically, a stack of a substrate 1, a first electrode 2, a second electron transport layer 7, a first electron transport layer 3 and a photoelectric conversion layer 4 was used as a measurement sample. The measurement sample did not include a hole transport layer 5 or a second electrode 6. In other words, the measurement sample had the photoelectric conversion layer 4 on its surface.

The measurement sample was subjected to ultraviolet electron spectroscopy measurement using an ultraviolet electron spectroscopy measurement device (produce name: PHI 5000 VersaProbe manufactured by ULVAC-PHI, INCORPORATED), and the energy level at the upper end of the valence band of the perovskite compound in the photoelectric conversion layer 4 was calculated.

The measurement sample was subjected to transmittance measurement using a transmittance measuring device (SolidSpec-3700 manufactured by Shimadzu Corporation). Based on the results of the transmittance measurement, the bandgap of the perovskite compound in the photoelectric conversion layer 4 was calculated.

Based on the energy level at the upper end of the valence band and the bandgap calculated above, the energy level at the lower end of the conduction band of the perovskite compound in the photoelectric conversion layer 4 was calculated.

### Method for Measuring Porosity in Porous Material of First Electron Transport Layer 3

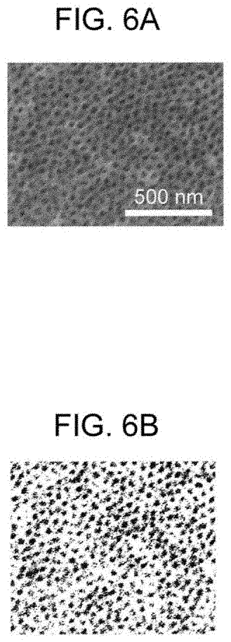

The porosity in the porous material of the first electron transport layer 3 was measured based on a SEM image of the surface of the porous material of the first electron transport layer 3 taken with field emission scanning electron microscope SU8200 (manufactured by Hitachi High-Tech Corporation). To clarify the contrast between void regions and solid regions in the SEM image of the surface of the porous material of the first electron transport layer 3, the SEM image was converted to gray scale format. This processing of the SEM image of the surface of the porous material will be described in detail while taking as an example the SEM image of the surface of the porous niobium oxide in the first electron transport layer 3 of EXAMPLE 2. FIG. 6A illustrates the SEM image of the porous niobium oxide in the first electron transport layer 3 of EXAMPLE 2. Specifically, first, the SEM image of the porous niobium oxide illustrated in FIG. 6A was provided. Next, the SEM image was binarized with “ImageJ” (manufactured by NIH) while presetting the automatic threshold setting method to Default, the minimum threshold value to 0, and the maximum threshold value to 50. FIG. 6B illustrates the SEM image of the porous niobium oxide of EXAMPLE 2 after binarization. This binarization processing identified bright parts (white parts in FIG. 6B) as solid regions, and dark parts (black parts in FIG. 6B) as void regions. As a result, the proportion of the range thresholded in the binarization processing relative to the whole (that is, the proportion of the area of the void regions in the total area of the solid regions and the void regions) was found to be 22.2%. The proportion thus obtained of the area of the void regions in the total area of the solid regions and the void regions was taken as the porosity.

### Method for Measuring Average Pore Diameter of Porous Material of First Electron Transport Layer 3

The pore diameter of the porous material of the first electron transport layer 3 was determined with respect to a SEM image of the surface of the porous material of the first electron transport layer 3 taken with field emission scanning electron microscope SU8200 (manufactured by Hitachi High-Tech Corporation). Thirty pores were selected at random from among the pores seen in the SEM image of the surface of the porous material of the first electron transport layer 3. Here, dark parts in the SEM image were recognized as pores. The diameters of the thirty pores selected were measured as the pore diameters. In the case where a single pore had a plurality of values of diameter (for example, when the shape of the pore was elliptical), the value of the smallest diameter was adopted as the value of diameter of that pore. The values of pore diameter measured of the thirty pores were averaged to give an average pore diameter. The pore diameters of the thirty void regions recognized as pores in the porous material of the first electron transport layer 3 were measured using “ImageJ” (manufactured by NIH).

### Nb/O Molar Ratio in Porous Niobium Oxide in First Electron Transport Layer 3

The composition of the porous niobium oxide forming the first electron transport layer 3 was determined with X-ray photoelectron spectroscopy measurement device (PHI 5000 VersaProbe (ULVAC-PHI, INCORPORATED)). Specifically, a stack of a substrate 1, a first electrode 2, a second electron transport layer 7 and a first electron transport layer 3 was used as a measurement sample. The measurement sample did not include a photoelectric conversion layer 4, a hole transport layer 5 or a second electrode 6. In other words, the measurement sample had the first electron transport layer 3 on its surface.

### Evaluation of Conversion Efficiency and Short-circuit Current

The solar cells 200 of EXAMPLES 1 to 5 and COMPARATIVE EXAMPLES 1 to 6 were irradiated with pseudo sunlight having an intensity of 100 mW/cm² from a solar simulator (BPS X300BA manufactured by Bunkoukeiki Co., Ltd.) to determine the conversion efficiency and the short-circuit current of each solar cell 200. The conversion efficiency and the short-circuit current are described in Table 1.

Table 1 describes the solar cells 200 of EXAMPLES 1 to 5 and COMPARATIVE EXAMPLES 1 to 6, specifically, describes the electron transporting materials (the material of the first electron transport layer 3 and the material of the second electron transport layer 7), the crystallinity of the material of the first electron transport layer 3, the photoelectric conversion material, the average pore diameter of the material of the first electron transport layer 3, the porosity in the porous material of the first electron transport layer 3, the conversion efficiency of the solar cell 200, and the short-circuit current of the solar cell 200.

TABLE 1

| | Electron transporting | | | | | | | | |
|---|---|---|---|---|---|---|---|---|---|
| | materials | | | Material (porous material) of first electron | | | | | |
| | Material of | Material of | | transport layer | | | | Solar cell | |
| | first | second | | | | Average | | | Short- |
| | electron | electron | Photoelectric | | | pore | Molar | Conversion | circuit |
| | transport | transport | conversion | | Porosity | diameter | ratio | efficiency | current |
| | layer | layer | material | Crystallinity | (%) | (nm) | Nb/O | (%) | (mA/cm²) |
| Ex.1 | Porous | Dense | FA_{0.83}PEA_{0.17}SnI₃ | Amorphous | 18.3 | 5.06 | 0.38 | 3.23 | 14.55 |
| | niobium | niobium | | | | | | | |
| | oxide | oxide | | | | | | | |
| Ex.2 | Porous | Dense | FA_{0.83}PEA_{0.17}SnI₃ | Amorphous | 22.2 | 38.45 | 0.38 | 3.13 | 14.62 |
| | niobium | niobium | | | | | | | |
| | oxide | oxide | | | | | | | |
| Ex.3 | Porous | Dense | FA_{0.83}PEA_{0.17}SnI₃ | Amorphous | 35.0 | 75.34 | 0.34 | 2.46 | 9.39 |
| | niobium | niobium | | | | | | | |
| | oxide | oxide | | | | | | | |
| Ex.4 | Porous | Dense | FA_{0.83}PEA_{0.17}SnI₃ | Amorphous | 26.3 | 131.39 | Not | 2.40 | 9.19 |
| | niobium | niobium | | | | | measured | | |
| | oxide | oxide | | | | | | | |
| Ex.5 | Porous | Dense | FA_{0.83}PEA_{0.17}SnI₃ | Crystal | 23.7 | 21.6 | 0.37 | 2.28 | 12.80 |
| | niobium | niobium | | | | | | | |
| | oxide | oxide | | | | | | | |
| Comp. | — | Dense | FA_{0.83}PEA_{0.17}SnI₃ | — | — | — | — | 1.71 | 6.28 |
| Ex.1 | | niobium | | | | | | | |
| | | oxide | | | | | | | |
| Comp. | — | Dense | FA_{0.83}PEA_{0.17}PbI₃ | — | — | — | — | 0.03 | 0.60 |
| Ex.2 | | niobium | | | | | | | |
| | | oxide | | | | | | | |
| Comp. | Porous | Dense | FA_{0.83}PEA_{0.17}PbI₃ | Amorphous | 18.3 | 5.06 | 0.38 | 0.46 | 5.76 |
| Ex.3 | niobium | niobium | | | | | | | |
| | oxide | oxide | | | | | | | |
| Comp. | Porous | Dense | FA_{0.83}PEA_{0.17}SnI₃ | Not | Not | Not | — | 0.54 | 21.27 |
| Ex.4 | zinc | zinc | | measured | measured | measured | | | |
| | oxide | oxide | | | | | | | |
| Comp. | Porous | Dense | FA_{0.83}PEA_{0.17}SnI₃ | Not | Not | Not | — | 0.01 | 0.28 |
| Ex.5 | aluminum | aluminum | | measured | measured | measured | | | |
| | oxide | oxide | | | | | | | |
| Comp. | Porous | Dense | | Not | Not | Not | — | 0.00 | 0.14 |
| Ex.6 | zirconium | zirconium | FA_{0.83}PEA_{0.17}SnI₃ | measured | measured | measured | | | |
| | oxide | oxide | | | | | | | |

As can be seen from the above results, a high short-circuit current and high conversion efficiency are achieved by the solar cells 200 of EXAMPLES 1 to 5 that include a photoelectric conversion layer 4 containing a tin-based perovskite compound as a photoelectric conversion material, and a first electron transport layer 3 containing porous niobium oxide.

The solar cells 200 of EXAMPLES 1 to 5 in which the photoelectric conversion material is a tin-based perovskite compound and the porous material contained in the first electron transport layer 3 is niobium oxide exhibit high conversion efficiency. This is because the energy offset between the niobium oxide and the tin-based perovskite compound is small. In the solar cell 200 of COMPARATIVE EXAMPLE 3 in which the porous material contained in the first electron transport layer 3 is niobium oxide but the photoelectric conversion material is a lead-based perovskite compound, the conversion efficiency is low probably because the energy offset is large.

In the solar cell 200 of EXAMPLE 5, the porous niobium oxide contained in the first electron transport layer 3 was a crystal, whereas in the solar cells 200 of EXAMPLES 1 to 4, the porous niobium oxide contained in the first electron transport layer 3 was amorphous. The solar cells 200 of EXAMPLES 1 to 4 in which the porous niobium oxide was amorphous had higher conversion efficiency than the solar cell 200 of EXAMPLE 5 in which the porous niobium oxide was a crystal.

The solar cells of the present disclosure are useful and environmentally superior tin-based perovskite solar cells that can attain high conversion efficiency.

What is claimed is:

1. A solar cell comprising:
a first electrode;
a second electrode;
a photoelectric conversion layer disposed between the first electrode and the second electrode; and
a first electron transport layer disposed between the first electrode and the photoelectric conversion layer, wherein
at least one electrode selected from the group consisting of the first electrode and the second electrode has translucency,
the photoelectric conversion layer comprises a perovskite compound containing a monovalent cation, a Sn cation and a halogen anion, and
the first electron transport layer comprises porous niobium oxide.

2. The solar cell according to claim 1, further comprising:
a second electron transport layer disposed between the first electrode and the first electron transport layer and comprising compact niobium oxide.

3. The solar cell according to claim 1, wherein
the porous niobium oxide is amorphous.

4. The solar cell according to claim 1, wherein
the monovalent cation comprises at least one selected from the group consisting of formamidinium cation and methylammonium cation.

5. The solar cell according to claim 1, wherein
the halogen anion comprises iodide ion.

6. The solar cell according to claim 1, further comprising:
a hole transport layer disposed between the second electrode and the photoelectric conversion layer.

7. The solar cell according to claim 1, wherein
the porous niobium oxide has an average pore diameter of greater than or equal to 1 nm and less than or equal to 132 nm.

8. The solar cell according to claim 1, wherein
the porous niobium oxide has a porosity of greater than or equal to 5% and less than or equal to 35%.

9. The solar cell according to claim 1, wherein
the porous niobium oxide has a Nb/O molar ratio of greater than or equal to 0.31 and less than or equal to 0.41.
